(19) United States
(12) Patent Application Publication
(10) Pub. No.: US 2008/0157295 A1
(43) Pub. Date: Jul. 3, 2008

(54) METHODS AND APPARATUS FOR MULTICHIP MODULE PACKAGING

(75) Inventors: Peter R. Nuytkens, Melrose, MA (US); Noureddine Hawat, Woburn, MA (US); Joseph M. Kulinets, North Andover, MA (US)

Correspondence Address: GOODWIN PROCTER LLP;PATENT ADMINISTRATOR, EXCHANGE PLACE, BOSTON, MA, 02109-2881, US

(73) Assignee: Custom One Design, Inc., Melrose, MA (US)

(21) Appl. No.: 11/961,984

(22) Filed: Dec. 20, 2007

Related U.S. Application Data
(60) Provisional application No. 60/875,972, filed on Dec. 20, 2006.

(51) Int. Cl. H01L 23/498; H01L 21/98

(52) U.S. Cl. 257/659; 257/686; 438/109; 257/E23.063; 257/E21.705

(57) ABSTRACT

Methods and apparatus for multichip modules having improved shielding and isolation properties.

### CROSS-REFERENCE TO RELATED APPLICATIONS

This application claims the benefit of U.S. Provisional Patent Application No. 60/875,972, filed on Dec. 20, 2006, which is hereby incorporated by reference as if set forth herein in its entirety.

### FIELD OF THE INVENTION

The present invention relates to methods and apparatus for the packaging of integrated circuits, and in particular to the packaging of a plurality of integrated circuits in a module.

### BACKGROUND OF THE INVENTION

Modern electronic devices typically include one or more integrated circuits (ICs). In order to operate, each integrated circuit must have electrical connections to other components, such as a power supply. This is typically achieved through the use of a package surrounding the integrated circuit and one or more solder bonds or pin-and-socket connections to join the package to a substrate.

The package is often disproportionately large relative to the integrated circuit that it contains, and size reduction and performance improvement may be realized by aggregating several integrated circuits into a single package. The package may also include discrete passive components, providing a complete functional unit for design purposes.

Several such techniques for creating a system-in-package (SIP) or multichip module (MCM) are known to the prior art. However, these known methods suffer from several drawbacks. In particular, a complete functional unit that requires both analog and digital circuits, such as a radio frequency transceiver, may require additional shielding or design measures to operate properly when packaged together.

Accordingly, there is a need for improved multichip modules and packaging methods.

### SUMMARY OF THE INVENTION

The present invention addresses the shortcomings of existing packaging techniques by providing multichip packaging having improved performance.

In a first aspect, the present invention provides a multichip module comprising a substrate having a first side and a second side, at least one electrical component in electrical and physical contact with the second side of the substrate, and a contact landing facility protruding beyond the at least one electrical component to establish electrical contact between the substrate and a contact plane of the module. The substrate may be, e.g., a printed circuit board having at least two layers. Suitable electrical components include integrated circuits and other discrete electronic components.

In one embodiment, the module further includes at least one electrical component in electrical and physical contact with the first side of the substrate. Electrical contact between electrical components and the substrate may be provided using wire bonding, a flip-chip connection using studs or solder balls, etc. Electrical contact between electrical components and the first side of the substrate may be established using a solder having the same or a lower melting temperature than the solder used to establish electrical contact between electrical components and the second side of the substrate.

In one embodiment, the contact landing facility comprises a printed circuit board having at least one opening to accommodate the at least one electrical component placed on the second side of the substrate and the facility is in physical and electrical contact with the second side of the substrate. In another embodiment, the substrate comprises a layer comprising a metal pattern and the contact landing facility comprises a printed circuit board having at least one via that together with the metal pattern forms an electrical shield enclosing the at least one electrical component. In still another embodiment the contact landing facility comprises a metal pin frame in physical and electrical contact with the second side of the substrate.

In still another aspect, the present invention provides a multichip module comprising a plurality of substrates, each substrate having: a first and a second side, at least one electrical component in electrical and physical contact with the second side of each substrate, and a contact landing facility to establish electrical contact between each substrate and the contact plane for that substrate, with the contact landing facility of each substrate in physical and electrical contact at the level of a contact plane with the first side of the immediately-adjacent substrate.

In one embodiment of the multichip module, the contact plane for each substrate is spaced from the substrate to accommodate the maximum height of the electrical components placed on the second side of the substrate and any electrical components on the facing side of the immediately-adjacent substrate.

In still another aspect, the present invention provides a method for creating a multichip module. A substrate is provided having a first and second side, and a first integrated circuit is provided in physical proximity to the first side of the substrate using, e.g., a first solder for establishing electrical connections between the substrate and the first integrated circuit. The substrate, the first integrated circuit and the first solder are heated at a first temperature to melt the first solder and establish electrical connections between the substrate and the first integrated circuit. A second integrated circuit is then provided in physical proximity to the second side of the substrate. A second solder having a melting temperature equal to or less than that of the first solder is used for establishing electrical connections between the substrate and the second integrated circuit. The substrate, the second integrated circuit, and the second solder are heated at a second temperature equal to or less than the first temperature to melt the second solder and establish electrical connections between the substrate and the second integrated circuit. Finally, a structure is affixed to the second side of the substrate that at least partially surrounds the second integrated circuit.

In some embodiments, the structure that is affixed to the second side of the substrate completely surrounds the second integrated circuit. In other embodiments, affixing the structure includes affixing an isolation element barrier. Affixing the structure may also include establishing an isolation barrier between the first integrated circuit and the second integrated circuit. The method for creating a multichip module may also include establishing electrical contact between the multichip module and a second substrate.

The foregoing and other features and advantages of the present invention will be made more apparent from the description, drawings, and claims that follow.

### BRIEF DESCRIPTION OF DRAWINGS

The advantages of the invention may be better understood by referring to the following drawings taken in conjunction with the accompanying description in which:

FIG. 1 presents a cross-section view of one embodiment of the present invention providing a system-in-package pin-lead module (SIPPL);

FIG. 2 depicts a cross-section view of one embodiment of the present invention providing a system-in-package formed lead module (SIPFL);

FIG. 3 illustrates a cross-section view of one embodiment of the present invention providing a system-in-package module;

FIG. 4A presents a cross-section view of one embodiment of the present invention providing a multichip module attached to a printed circuit board (PCB) using surface-mount technology (SMT);

FIG. 4B depicts a cross-section view of the module of FIG. 4A using wire bonds to establish electrical connection between an integrated circuit and the substrate;

FIG. 4C depicts a cross-section view of the module of FIG. 4B mounted on a printed circuit board;

FIG. 4D depicts another embodiment of the present invention having a contact landing facility in the form of a metal pin frame;

FIG. 5 illustrates a cross-section view of another embodiment of the present invention providing a multichip module attached to a PCB using surface-mount technology (SMT);

FIG. 6 presents a cross-section view of yet another embodiment of the present invention providing a multichip module attached to a PCB using surface-mount technology (SMT);

FIG. 7 presents a stacked three-dimensional multichip module structure in accord with one embodiment of the present invention; and

FIG. 8 depicts a flowchart of a method for manufacturing various embodiments of the present invention.

In the drawings, like reference characters generally refer to corresponding parts throughout the different views. The drawings are not necessarily to scale, emphasis instead being placed on the principles and concepts of the invention.

### DETAILED DESCRIPTION OF THE INVENTION

The present invention addresses the shortcomings of prior art MCMs by providing MCMs having improved shielding and isolation properties.

### System-in-Package Pin-Lead Module

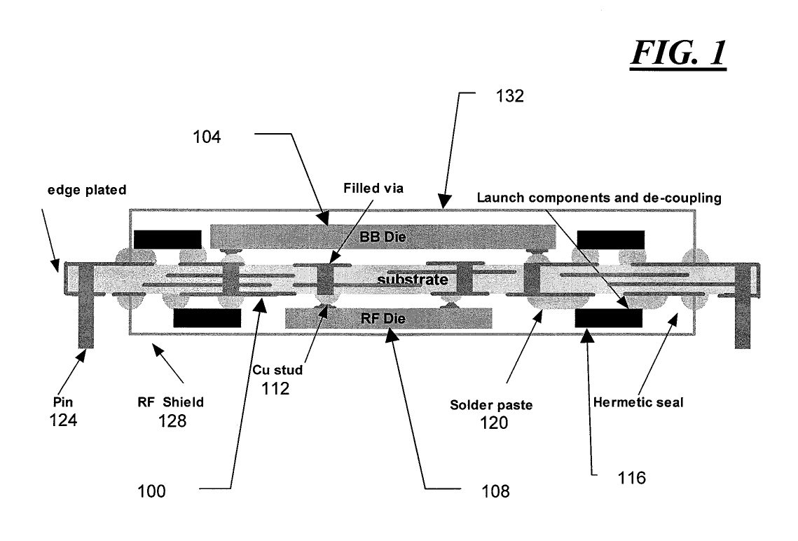

With reference to FIG. 1, one embodiment of the present invention provides an MCM using a multilayer substrate 100 to provide electrical connections as well as an electrical shielding between a baseband die 104 and a radio-frequency die 108. The copper bumps 112 are connected to the pads of dies 104 and 108 to facilitate the attachment of the dies 104, 108 to the substrate 100 Solder paste 120 is applied to the particular areas of the substrate 100 corresponding to the bumps 112 and contacts of discrete components 116 to be included in the package and heated until it melts, forming electrical connections between the dies 104, 108 and components 116 and the substrate 100.

Although the multilayer substrate 100 potentially provides better shielding between the baseband die 104 and the radio frequency die 108, a better shielding effect can be achieved by enclosing the RF components into the shielding enclosures. This, in turn, is addressed through the use of RF shields 128, 132 to reduce interference between the baseband die 104 and the radio frequency die 108, and the dies 104, 108 and the outside world.

### System-in-Package Formed Lead Module

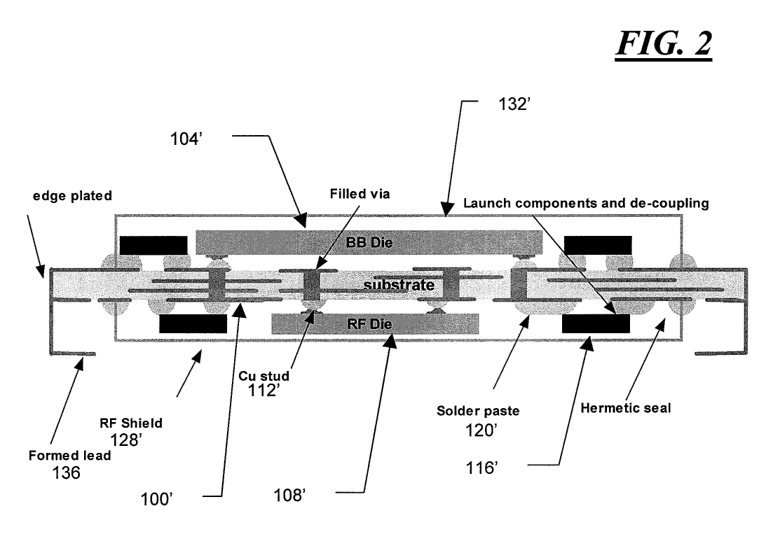

The embodiment of FIG. 2 is similar to the SIPPL embodiment of FIG. 1, except that formed leads 136 are used in lieu of pins to form connections with the MCM.

With reference to FIG. 2, a multilayer substrate 100′ provides electrical connections as well as an electrical shielding between a baseband die 104′ and a radio-frequency die 108′. The copper bumps 112′ are connected to the pads of dies 104′ and 108′ to facilitate the attachment of the dies 104′, 108′ to the substrate 100′ Solder paste 120′ is applied to the particular areas of the substrate 100′ corresponding to the bumps 112′ and contacts of discrete components 116′ to be included in the package. and heated until it melts, forming electrical connections between the dies 104′, 108′ and components 116′ and the substrate 100′.

In this embodiment, formed leads 136 are used to make external connections with the MCM. Although this does reduce the shielding effect of the substrate 100′, the reduction is not as pronounced as the reduction associated with the SIPPL embodiment. Like the embodiment of FIG. 1, the shielding effect is augmented by the use of RF shields 128′, 132′ to reduce interference between the baseband die 104′ and the radio frequency die 108′, and the dies 104′, 108′ and the outside world.

### System-in-Package Module

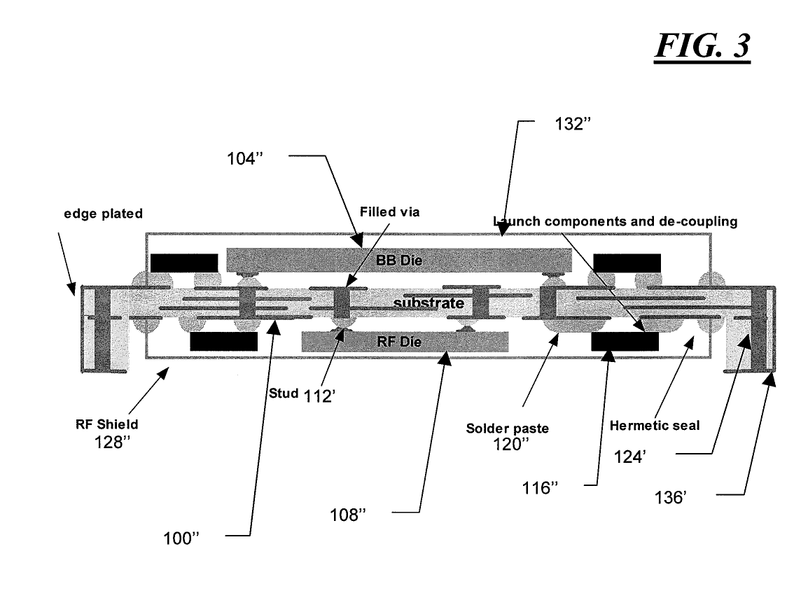

The embodiment of FIG. 3 is similar to the SIPPL embodiment of FIG. 1 and the SIPFL embodiment of FIG. 2, except that external connections are made with the MCM using a combination of pins 124′ and formed leads 136′.

With reference to FIG. 3, a multilayer substrate 100″ provides electrical connections as well as an electrical shielding between a baseband die 104″ and a radio-frequency die 108″. The copper bumps 112″ are connected to the pads of dies 104″ and 108″ to facilitate the attachment of the dies 104″, 108″ to the substrate 100″ Solder paste 120″ is applied to the particular areas of the substrate 100″ corresponding to the bumps 112″ and contacts of discrete components 116″ to be included in the package. and heated until it melts, forming electrical connections between the dies 104″, 108″ and components 116″ and the substrate 100″.

In this embodiment, pins 124′ and formed leads 136′ are used to make external connections with the MCM. This significantly reduces the shielding effect associated with the substrate 100″. Like the embodiments of FIGS. 1 and 2, the shielding effect is strengthened by the use of RF shields 128″, 132″ to reduce interference between the baseband die 104″ and the radio frequency die 108″, and the dies 104″, 108″ and the outside world.

### Use of Printed Circuit Boards as Contact Landing Facility

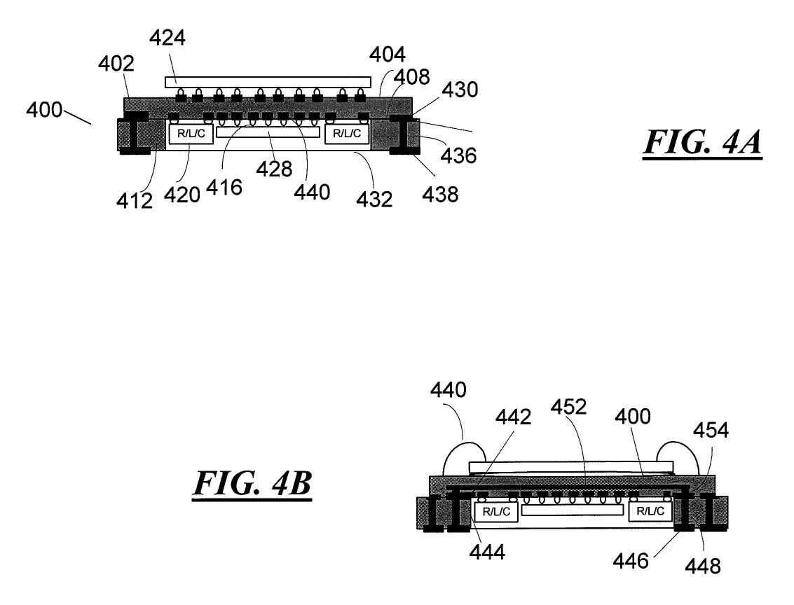

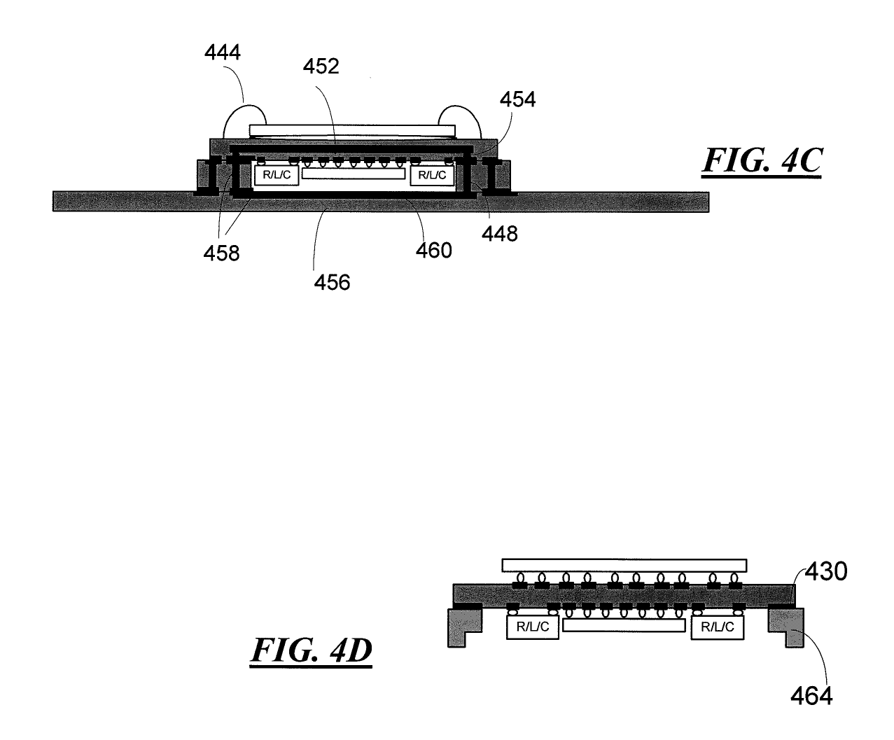

With reference to FIG. 4A, another embodiment of the present invention shows a module 400 utilizing a multilayer substrate 402 having a first side 404 and a second side 408. Solder bumps 416 formed on the pads of the dies 424 and 428 are used to attach dies 424, 428 to the first side 404 and the second side 408 of the substrate 402 using surface-mount technology (SMT). Solder may also be used to attach discrete components 420 to the first side 404 and the second side 408 of the substrate 402. The dies 424, 428 may be, for example, baseband or radio frequency dies. There can be a few dies on either side of the substrate 402 or no dies at all. There can be additional discrete components on either side of the substrate 402 or no electrical components at all.

In accord with embodiments of the present invention, the solder used on one side of the substrate 402 may have the same melting point or a lower melting point that the solder used on the other side of the substrate.

The exposed contact pads 410 on the second side 408 of the multilayer substrate 402 are used to provide the electrical connection between the dies and discrete components placed on both sides of multilayer substrate 402 and surrounding world through the external contacts 438.

The external contacts 438 that connect the module to the external world are physically arranged in a geometrical plane, forming the contact plane 432. The contact landing facility that have a form of printed circuit board 412 provides the electrical connection between the contacts 410 and external contacts 438. The printed circuit board 412 has at least two layers. The exposed contact pads 430 on the second side 408 of the substrate 402 are positioned accordingly and electrically connected through the soldering or other means of electrical connection to the exposed contact pads 418 on the first side of the printed circuit board 412.

The contact landing facility—printed circuit board 412 can be of rectangular shape and have a rectangular or other shape hole in it, large enough to accommodate the dies 428 and discrete components 420 The electrical vias 436 in the contact landing facility 412 are used to connect the exposed pads 438 positioned in a contact plane 432 to the substrate 402. More complicated printed circuit board 412 can be used to change the contact arrangement of external contacts 438 relative to the arrangement of contacts 430 and 418 the so called contact or pin re-distribution.

FIG. 4B presents another embodiment of the present invention that is similar to the embodiment of FIG. 4A. As depicted, this embodiment utilizes wire bonds 444 to electrically connect the upper die to the first side of the substrate. Another feature shown in FIG. 4B is the possibility to form the electrical shielding for the dies and discrete components placed on the second side of the substrate 402. To provide a possibility of an electrical shielding one of the layers of the substrate 402 has an electrical shield 452 connected through the external shielding vias 454 to the exposed contact pads 442 on the second side of the substrate 402. The vias 454 and contact pads 442 are uniformly spread over the perimeter of the shield 452 to form the part of a shielding cage. The contact landing facility—printed circuit board 412 has correspondent contacts 444 on the first side, shielding vias 448 that are the continuation of the shielding vias 454 inside the substrate 402, and external contacts 446 that together form the continuation of a shielding cage. The density of the shielding vias 448 and 453 should be sufficient to provide the required electrical shielding

FIG. 4C presents the embodiment of FIG. 4B mounted on an application printed circuit board 456 that, together with the shielding arrangements described in accordance with the FIG. 4B, forms a shielding cage 458. To close the electrical shielding cage 458, the application PCB 456 has an electrical shield 460 formed in one of its layers and connected via respective external contacts and internal vias (if needed) to the corresponding shielding ground or other shielding potential inside the application PCB 456.

FIG. 4D presents another embodiment of FIG. 4A where a contact landing facility 464 represents a metal pin frame 464 instead of a PCB 412. The contact landing facility 412 essentially represents a multiplicity of the separate metal landing pins etched in a thick metal foil formed using known methods for manufacturing QFN integrated circuit packages. The thickness of a pin frame 464 should be enough to accommodate the tallest dies and discrete components placed on the second side of the substrate 402.

In the process of manufacturing the individual pins are etched in the form of a combined frame with the separate pins soldered to the respective contacts 430 on the second side of substrate 402. After soldering the individual pins are separated from each other using such known methods as punching or sawing.

### MCM Mounting

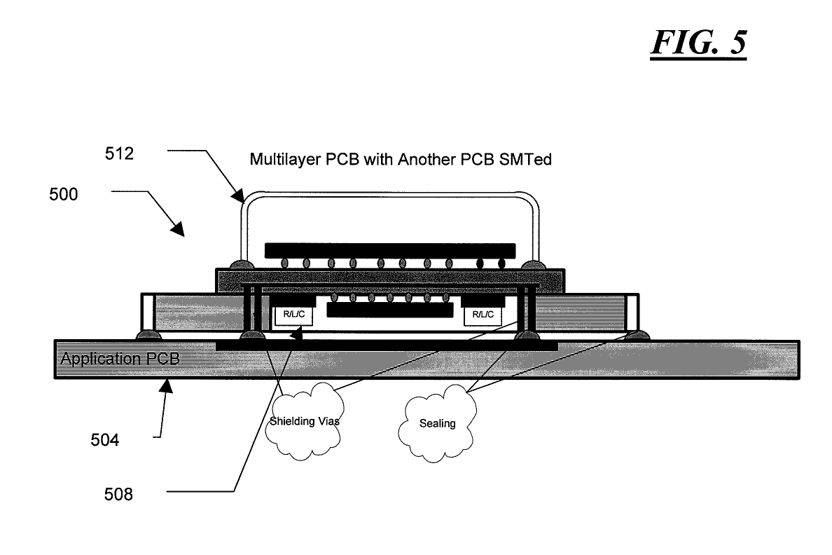

Any of the previously discussed embodiments may be attached to a PCB in the course of assembling an electronic device. For example, FIG. 5 depicts the MCM 500 of FIG. 4A mounted on a PCB 504. As depicted in FIG. 5, after the dies and substrate are assembled, various discrete components 508 may be added to the MCM 500 before it is attached to the PCB 504. Additional shielding 512 may be added to the MCM 500.

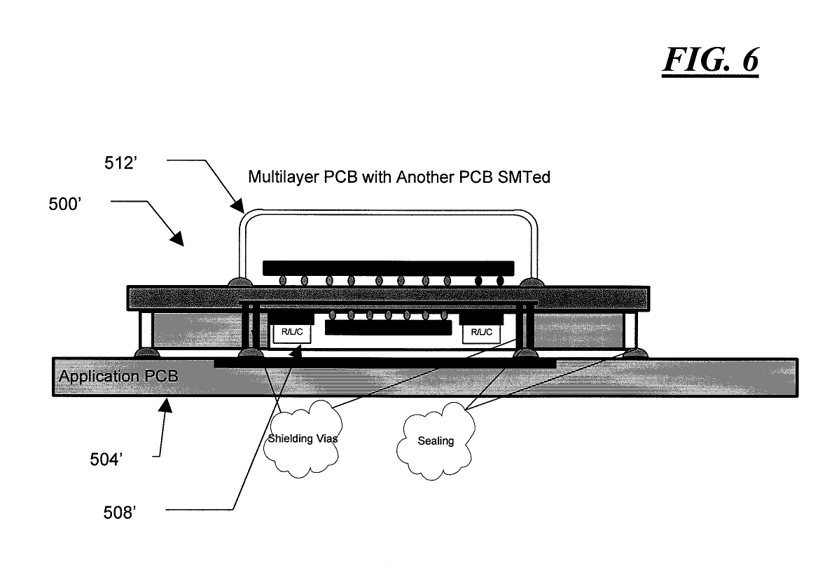

FIG. 6 depicts another embodiment of the MCM 500′ mounted on a PCB 504′. As depicted in FIG. 6, after the dies and substrate are assembled, various discrete components 508′ may be added to the MCM 500′ before it is attached to the PCB 504′. Additional shielding 512′ may be added to the MCM 500′.

### Stacked Three-Dimensional Module.

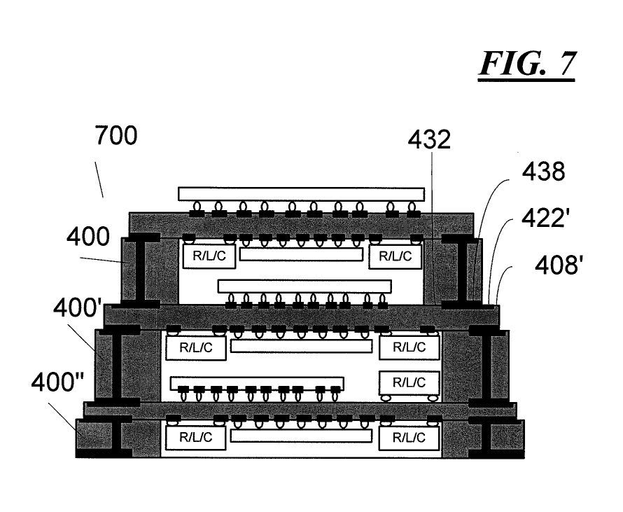

FIG. 7 presents a stacked three-dimensional implementation 700 of MCMs. The stacked three-dimensional module 700 is formed by a few component modules 400, 400′, and 400″ placed one on the top of another in such configuration that the contact landing facility of each module is in physical and electrical contact at the level of its contact plane with the first side of the immediately-adjacent substrate. For example, the contact plane 432 of the component module 400 is coincidental with the first side 408′ of the second component module 400′. The positions of external contacts 438 in the contact plane 432 of component module 400 are matching the positions of respective contacts 422′ on the first side of the adjacent component module 400′.

The component modules are physically and electrically connected to each other by soldering external pads at the contact plane of one component module to the respective contact pads on the first side of the substrate of the adjacent component module. To do so the solder can be discretely dispensed on the respective contact pads on the first side of the substrate of each module before the final tunnel oven soldering. The melting temperature of the solder used for the final assembly of the stacked module can be equal or lower than the melting temperature of the solder used during assembly of the component modules.

### MCM Assembly

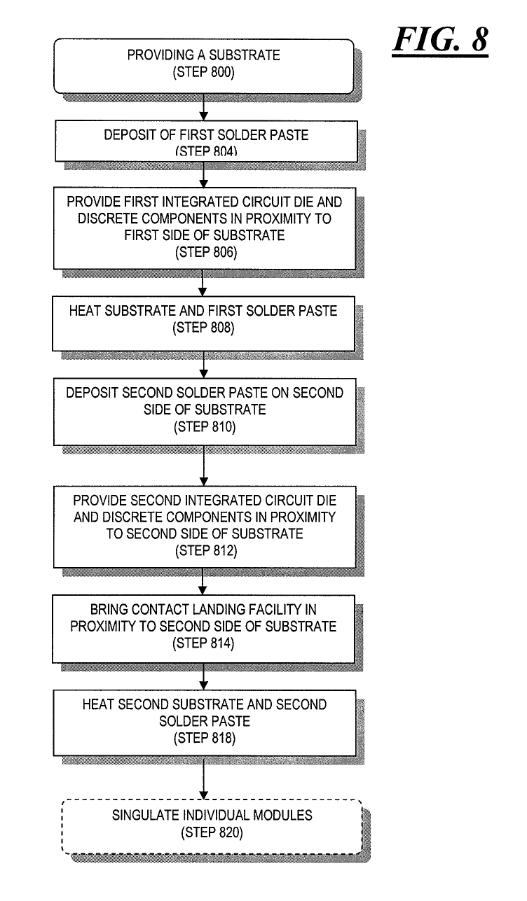

As discussed above, with reference to FIG. 8, a multichip module may be fabricated in accord with the present invention by providing a substrate having a first side and a second side (Step 800). Simultaneously a multiplicity of modules can be assembled, so the original substrate printed circuit board can be a strip or panel containing many individual substrates The high-temperature solder paste is deposited in required places and amount on the first side of the substrate panel using known methods and tools. For each individual module a first bumped integrated circuit die (or multiple dies) and other discrete components are provided in physical proximity to the first side of the particular individual substrate on the substrate panel using existing pick-and-place tools (Step 806).

The substrate panel and the deposited high-temperature solder are heated to melt the high-temperature solder and establish electrical connections between the substrate and first integrated circuit die and discrete components (Step 808).

The substrate panel with dies and discrete components soldered to its first side is turned over. The second solder paste having a melting temperature lower than that of the high-temperature solder is deposited in required places and amount on the second side of the substrate using known methods and tools (Step 810). A second integrated circuit die and discrete components are provided in physical proximity to the second side of the substrate panel using existing pick-and-place tools (Step 812).

A multiplicity of contact landing facilities in a form of the printed circuit boards for a multiplicity of modules can be combined on one strip or printed circuit panel containing many individual contact landing facilities for a multiplicity of modules. The same way, a multiplicity of contact landing facilities in a form of the pin frames for a multiplicity of modules can be combined on one strip or frame panel.

The strip or panel containing a multiplicity of contact landing facilities is brought in physical proximity to the second side of the substrate and aligned with it (Step 814).

The substrate panel and the second solder are heated to melt the second solder and establish electrical connections between the substrate, second integrated circuit dies, discrete parts and contact landing facilities panel (Step 818).

Once the assembly process is finished, the multichip module is singulated from the panel or strip using known punching or sawing tools (Step 820).

It will therefore be seen that the foregoing represents a highly advantageous approach to the provision of a multichip module. The terms and expressions employed herein are used as terms of description and not of limitation and there is no intention, in the use of such terms and expressions, of excluding any equivalents of the features shown and described or portions thereof, but it is recognized that various modifications are possible within the scope of the invention claimed.

What is claimed is:

1. A multichip module comprising:
a substrate having a first side and a second side,
at least one electrical component in electrical and physical contact with the second side of the substrate; and
a contact landing facility protruding beyond the at least one electrical component to establish electrical contact between the substrate and a contact plane of the module.

2. The multichip module of claim 1 wherein the substrate is a printed circuit board having at least two layers.

3. The multichip module of claim 1 wherein the electrical component is an integrated circuit or die.

4. The multichip module of claim 1 further comprising at least one electrical component in electrical and physical contact with the first side of the substrate.

5. The multichip module of claim 4 wherein electrical contact between the at least one electrical component and the substrate is provided through wire bonding.

6. The multichip module of claim 4 wherein electrical contact between the at least one electrical component and the substrate is provided as through a flip chip connection using studs or solder balls.

7. The multichip module of claim 4 wherein electrical contact between the at least one electrical component and the first side of the substrate is established using a solder having a melting temperature that is different from the melting temperature of the solder used during assembly of the second side of the substrate.

8. The multichip module of claim 1 wherein electrical contact the at least one electrical component and the substrate is established using a solder having a melting temperature that is equal to the melting temperature of the solder used during assembly of the other side of the substrate.

9. The multichip module of claim 1 wherein the contact landing facility comprises a printed circuit board having at least one opening to accommodate the at least one electrical component placed on the second side of the substrate, and the facility is in physical and electrical contact with the second side of the substrate.

10. The multichip module of claim 7 wherein the substrate comprises a layer comprising a metal pattern and the contact landing facility comprises a printed circuit board having at least one via that together with the metal pattern forms an electrical shield enclosing the at least one electrical component.

11. The multichip module of claim 1 wherein the contact landing facility comprises a metal pin frame in physical and electrical contact with the second side of the substrate.

12. A multichip module comprising:
a plurality of substrates, each substrate having:
a first side and a second side;
at least one electrical component in electrical and physical contact with the second side of each substrate;
a contact landing facility to establish electrical contact between each substrate and the contact plane for that substrate,
wherein the contact landing facility of each substrate is in physical and electrical contact at the level of a contact plane with the first side of the immediately-adjacent substrate.

13. The multichip module of claim 12 where the contact plane for each substrate is spaced from the substrate to accommodate the maximum height of the at least one electrical component placed on the second side of the substrate, and any electrical component placed on the facing side of the immediately-adjacent substrate.

14. A method for creating a multichip module, the method comprising:
providing a substrate having a first side and a second side;
depositing a first solder paste on the first side of the substrate;
providing at least one first electrical component in physical proximity to the first side of the substrate using the first solder paste to establish electrical connections between the substrate and the at least one first electrical component;
heating the substrate and the first solder paste at a first temperature to melt the first solder paste and establish electrical connections between the substrate and the at least one first electrical component;
depositing a second solder paste having a melting temperature equal to or lower than that of the first solder paste on the second side of the substrate;
providing at least one second electrical component in physical proximity to the second side of the substrate;
bringing the contact landing facility in physical proximity to the second side of the substrate and aligning the facility with the second side of the substrate;
heating the substrate, the contact landing facility and the second solder paste at a second temperature equal to or less than the first temperature to melt the second solder paste and establish electrical connections between the substrate, the contact landing facility, and the at least one second electrical component.

15. The method of claim 14 wherein the electrical components are integrated circuit, dies, or discrete electrical components.

16. The method of claim 14 further comprising:
iterating the method of claim 14 to create a plurality of multichip modules; and
singulating separate modules from the plurality.
